(19) United States
(12) Patent Application Publication
(10) Pub. No.: US 2026/0358692 A1
(43) Pub. Date: Nov. 12, 2026

(54) MASKS AND METHODS OF MANUFACTURING MASKS

(71) Applicant: Taiwan Semiconductor Manufacturing Company, Ltd., Hsinchu (TW)

(72) Inventors: Chun-Yao HSU, Hsinchu (TW); Ming-Che LI, Hsinchu (TW); Cheng-Kuang CHEN, Hsinchu (TW); Chih-Wei WEN, Hsinchu (TW)

(73) Assignee: Taiwan Semiconductor Manufacturing Company, Ltd., Hsinchu (TW)

(21) Appl. No.: 19/204,255

(22) Filed: May 9, 2025

(51) Int. Cl. G03F 1/24; G03F 1/52; G03F 1/54; G03F 1/80

(52) U.S. Cl. CPC G03F 1/24; G03F 1/52; G03F 1/54; G03F 1/80

(57) ABSTRACT

A method of manufacturing a mask includes plasma processing a capping layer formed over a reflective multilayer stack to form a compound layer. The mask includes a reflective multilayered stack disposed over a substrate, a capping layer disposed over the reflective multilayered stack, and an absorber layer disposed over the capping layer. An opening is formed in the absorber layer, and a compound layer is within the opening.

### BACKGROUND

Manufacturing challenges can arise when seeking to reduce the size and increase the complexity of semiconductor devices. When addressing such challenges, advanced lithography technologies, e.g., extreme ultraviolet (EUV) photolithography, have been utilized in semiconductor device manufacturing processes. EUV lithography employs a reflective photomask to irradiate a photoresist with patterned EUV radiation. The patterned EUV radiation can form a pattern in the photoresist, which can be used to form a pattern in a substrate under the photoresist. However, processes associated with the use, manufacturing, and cleaning of a photomask used in EUV lithography can adversely affect the performance of the photomask.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 shows an EUV lithography tool according to an embodiment of the disclosure.

FIG. 2 shows a schematic diagram of a detail of an EUV lithography tool according to an embodiment of the disclosure.

FIG. 3 shows a cross-sectional view of an EUV mask according to an embodiment of the disclosure.

FIGS. 4, 5, 6, 7, 8, 9, 10, 11, 12, 13, 14, and 15 show cross-sectional views of methods of manufacturing an EUV mask according to embodiments of the disclosure.

FIGS. 16A, 16B, and 16C show cross-sectional views of EUV masks according to embodiments of the disclosure.

FIG. 17 shows a schematic diagram of a plasma processing apparatus according to an embodiment.

FIGS. 18, 19, and 20 are flow charts of methods of manufacturing a mask according to embodiments of the disclosure.

FIG. 21 is a flow chart of a method of manufacturing a semiconductor device according to an embodiment of the disclosure.

### DETAILED DESCRIPTION

It is to be understood that the following disclosure provides many different embodiments, or examples, for implementing different features of the disclosure. Specific embodiments or examples of components and arrangements are described below to simplify the present disclosure. These are, of course, merely examples and are not intended to be limiting. For example, dimensions of elements are not limited to the disclosed range or values, but may depend upon process conditions and/or desired properties of the device. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity.

Further, spatially relative terms, such as “beneath,” “below,” “lower,” “above,” “upper,” “top,” “bottom,” “middle,” and the like, may be used herein for ease of description to describe one element or feature's relationship to another element(s) or feature(s) as illustrated in the figures, and do not preclude additional structures above or below or between the stated feature. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. In addition, the term “made of” may mean either “comprising” or “consisting of.”

Further, in the following fabrication process, there may be one or more additional operations between the described operations, and the order of operations may be changed. In the present disclosure, a phrase “one of A, B and C” means “A, B and/or C (A, B, C, A and B, A and C, B and C, or A, B and C), and does not mean one element from A, one element from B and one element from C, unless otherwise described. In the following embodiments, materials, configurations, dimensions, processes and/or operations as described with respect to one embodiment (e.g., one or more figures) may be employed in the other embodiments, and detailed description thereof may be omitted.

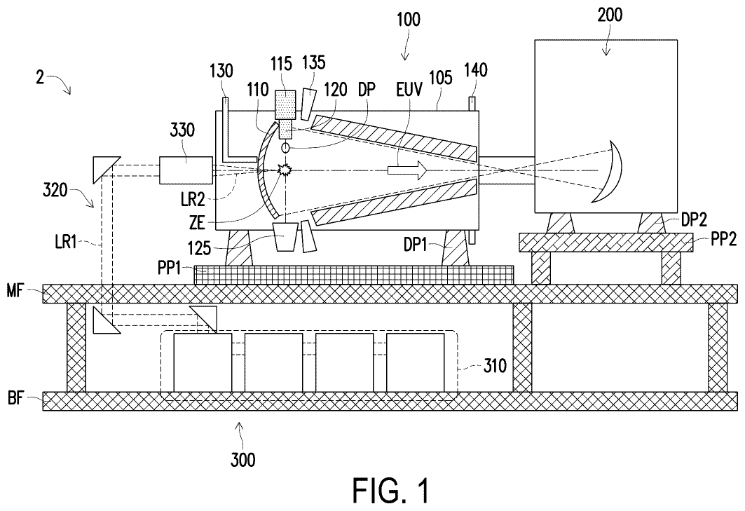

FIG. 1 is a schematic view of an EUV lithography tool 2, in accordance with some embodiments of the present disclosure. The EUV lithography tool 2 includes an EUV radiation source 100 to generate EUV radiation, an exposure device 200 such as a scanner, and an excitation laser source 300. The EUV radiation source 100 and the exposure device 200 are installed on a main floor MF of a clean room, while the excitation laser source 300 is installed in a base floor BF located under the main floor. Each of the EUV radiation source 100 and the exposure device 200 are placed over pedestal plates PP1 and PP2 via dampers DP1 and DP2, respectively. The EUV radiation source 100 and the exposure device 200 are coupled to each other by a coupling mechanism, which may include a focusing unit.

The EUV lithography tool 2 is designed to expose a resist layer to EUV light (also interchangeably referred to herein as EUV radiation). The resist layer is a material sensitive to the EUV light. The EUV lithography system employs the EUV radiation source 100 to generate EUV light, such as EUV light having a wavelength ranging between about 1 nm and about 100 nm. In one particular example, the EUV radiation source 100 generates an EUV light with a wavelength centered at about 13.5 nm. In the present embodiment, the EUV radiation source 100 utilizes a mechanism of laser-produced plasma (LPP) to generate the EUV radiation.

The exposure device 200 includes various reflective optic components, such as convex/concave/flat mirrors, a mask holding mechanism including a mask stage, and wafer holding mechanism. The EUV radiation generated by the EUV radiation source 100 is guided by the reflective optical components onto a mask secured on the mask stage. In some embodiments, the mask stage includes an electrostatic chuck (e-chuck) to secure the mask.

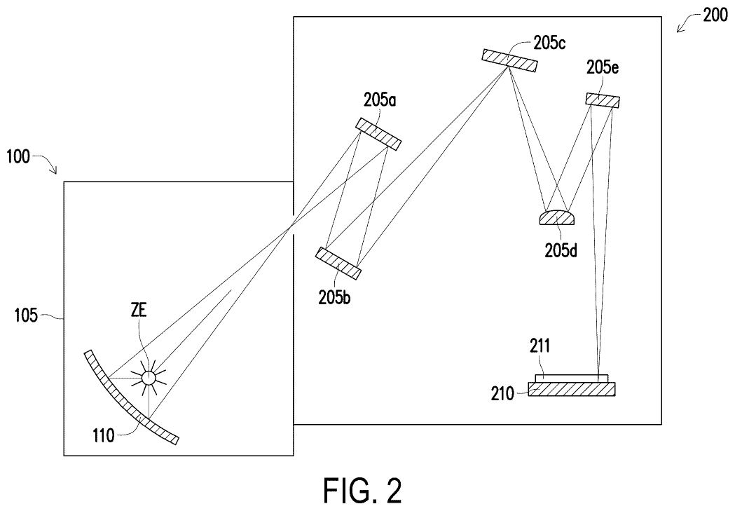

FIG. 2 is a schematic diagram of a detail of an extreme ultraviolet lithography tool according to an embodiment of the disclosure showing the exposure of a photoresist layer 211 coated on a substrate 210 with a patterned beam of EUV light. The exposure device 200 is an integrated circuit lithography tool such as a stepper, scanner, step and scan system, direct write system, a device using a contact and/or proximity mask, etc., provided with one or more optics 205a, 205b, for example, to illuminate mask 205c (also referred to as a reticle or photomask) with a beam of EUV light, to produce a patterned beam, and one or more reduction projection optics 205d, 205e, for projecting the patterned beam onto the photoresist layer 211 disposed on the substrate 210. In the present embodiment, the mask 205c is a reflective mask. A mechanical assembly (not shown) may be provided for generating a controlled relative movement between the substrate 210 and mask 205c. The EUV radiation source 100 includes an EUV light radiator ZE emitting EUV light in a chamber 105 that is reflected by a mirror collector 110 along a path into the exposure device 200 to irradiate the photoresist layer 211 on the substrate 210. In some embodiments, the substrate 210 is a semiconductor substrate. In some embodiments, the semiconductor substrate is a semiconductor wafer, such as a silicon wafer or other type of wafer to be patterned.

As shown in FIG. 1, the EUV radiation source 100 includes a target droplet generator 115 and a mirror collector 110, enclosed by a chamber 105. In some embodiments, the target droplet generator 115 includes a reservoir to hold a source material and a nozzle 120 through which target droplets DP of the source material are supplied into the chamber 105. In some embodiments, the target droplets DP are droplets of tin (Sn), lithium (Li), or an alloy of Sn and Li. In some embodiments, the target droplets DP each have a diameter in a range from about 10 microns (μm) to about 100 μm. For example, in an embodiment, the target droplets DP are tin droplets, having a diameter of about 10 μm to about 100 μm. In other embodiments, the target droplets DP are tin droplets having a diameter of about 25 μm to about 50 μm. In some embodiments, the target droplets DP are supplied through the nozzle 120 at a rate in a range from about 50 droplets per second (i.e., an ejection-frequency of about 50 Hz) to about 50,000 droplets per second (i.e., an ejection-frequency of about 50 kHz). A droplet catcher 125 is used for catching excessive target droplets. For example, some target droplets may be purposely missed by laser pulses.

In some embodiments, an excitation laser LR2 generated by the excitation laser source 300 is a pulse laser. The excitation laser source 300 may include a laser generator 310, laser guide optics 320, and a focusing apparatus 330. In some embodiments, a laser generator 310 includes a carbon dioxide (CO₂) or a neodymium-doped yttrium aluminum garnet (Nd:YAG) laser source with a wavelength in the infrared region of the electromagnetic spectrum. For example, the laser generator 310 has a wavelength of 9.4 μm or 10.6 μm, in an embodiment. The laser light LR1 generated by the excitation laser source 300 is guided by the laser guide optics 320 and focused into the excitation laser LR2 by the focusing apparatus 330, and then introduced into the EUV radiation source 100.

In some embodiments, the excitation laser LR2 includes a pre-heat laser and a main laser. In such embodiments, the pre-heat laser pulse (interchangeably referred to herein as the “pre-pulse) is used to heat (or pre-heat) a given target droplet to create a low-density target plume with multiple smaller droplets, which is subsequently heated (or reheated) by a pulse from the main laser, generating increased emission of EUV light. In some embodiments, the pre-heat laser pulses have a spot size of about 100 μm or less, and the main laser pulses have a spot size in a range of about 150 μm to about 300 μm. In some embodiments, the pre-heat laser and the main laser pulses have a pulse-duration in the range from about 10 ns to about 50 ns, and a pulse-frequency in the range from about 1 kHz to about 100 kHz. In some embodiments, the pre-heat laser and the main laser have an average power in the range from about 1 kilowatt (kW) to about 50 kW. The pulse-frequency of the excitation laser LR2 is matched with the ejection frequency of the target droplets DP in an embodiment.

The excitation laser LR2 is directed through windows (or lenses) into the zone of excitation ZE. The windows are made of a suitable material substantially transparent to the laser beams. The generation of the pulse lasers is synchronized with the ejection of the target droplets DP through the nozzle 120. As the target droplets move through the excitation zone, the pre-pulses heat the target droplets and transform them into low-density target plumes. A delay between the pre-pulse and the main pulse is controlled to allow the target plume to form and to expand to an optimal size and geometry. In some embodiments, the pre-pulse and the main pulse have the same pulse duration and peak power. When the main pulse heats the target plume, a high-temperature plasma is generated. The plasma emits EUV radiation, which is collected by the mirror collector 110. The mirror collector 110 further reflects and focuses the EUV radiation for the lithography exposing processes performed through the exposure device 200. In some embodiments, the mirror collector 110 is designed to have an ellipsoidal geometry. In some embodiments, the mirror collector 110 is designed with a proper coating material and shape to function as a mirror for EUV collection, reflection, and focusing.

In some embodiments, a coating material of the mirror collector 110 is similar to a reflective multilayer stack of the EUV mask. In some examples, a coating material of the mirror collector 110 includes a reflective multilayer (such as a plurality of Mo/Si film pairs) and may further include a capping layer (such as Ru or Rh) coated on the reflective multilayer to substantially reflect the EUV light. In some embodiments, the mirror collector 110 may further include a grating structure designed to effectively scatter the laser beam directed onto the mirror collector 110. For example, a silicon nitride layer is coated on the mirror collector 110 and is patterned to have a grating pattern.

In such an EUV radiation source 100, the plasma caused by the laser application creates physical debris, such as ions, gases and atoms of the droplet, as well as the desired EUV radiation. It is necessary to prevent the accumulation of material on the mirror collector 110 and also to prevent physical debris exiting the chamber 105 and entering the exposure device 200.

Because gas molecules absorb EUV light, the lithography system for the EUV lithography patterning can be maintained in a vacuum or a low-pressure environment to avoid EUV intensity loss. In some embodiments, a buffer gas is supplied from a first buffer gas supply 130 through the aperture in the mirror collector 110 by which the pulse laser is delivered to the tin droplets. In some embodiments, the buffer gas is H₂, He, Ar, N₂ or another inert gas. The buffer gas can also be provided through one or more second buffer gas supplies 135 toward the mirror collector 110 and/or around the edges of the mirror collector 110. Further, the chamber 105 includes one or more gas outlets 140 so that the buffer gas is exhausted outside the chamber 105. Hydrogen gas (H₂) has a low absorption to the EUV radiation. In certain embodiments, hydrogen gas can be energized by EUV radiation to generate hydrogen (H*) radicals. The hydrogen radicals can be used for cleaning purposes. Hydrogen radicals reaching the coating surface of the mirror collector 110 can react chemically with metal contamination from a droplet and form a hydride, e.g., metal hydride. When tin (Sn) is used as the droplet, hydrogen radicals can react with tin to form stannane (SnH₄), which is a gaseous byproduct of the EUV generation process. The gaseous SnH₄ can then then pumped out through the outlet 140.

In some embodiments, an EUV lithography tool can further include other modules or is integrated with (or coupled with) other modules in some embodiments.

A mask used in EUV lithography can include a reflective multilayered stack disposed over a substrate, one or more capping layers disposed over the reflective multilayered stack, and an absorber layer disposed over the one or more capping layers. In some embodiments, a compound layer including one or more rhodium compounds is provided over the one or more capping layers. The compound layer can enhance chemical resistivity and suppress the diffusion of ions into the reflective multilayered stack of the mask. The chemical resistance and protection of the reflective multilayered stack can extend the lifespan of the mask.

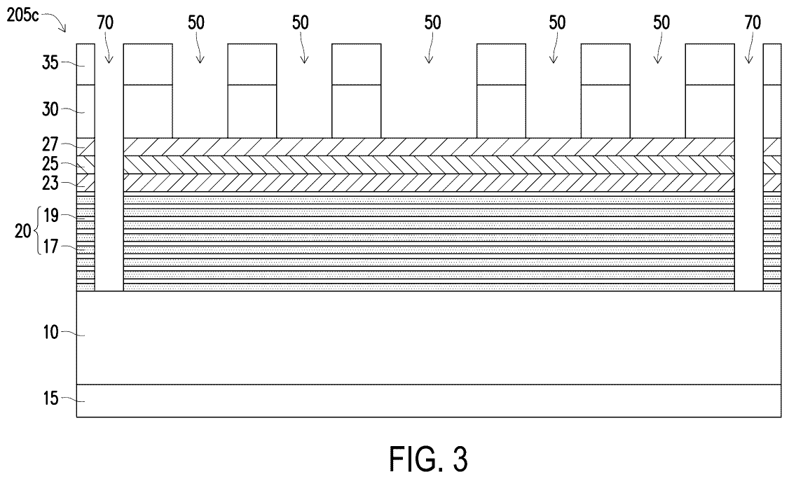

A mask can include a substrate made of a low thermal expansion material, such as titanium oxide doped silicon dioxide, or any other suitable low thermal expansion materials, such as fused silica, fused quartz, silicon, silicon carbide, Black Diamond, and/or any one or more other low thermal expansion substances known in the art that can minimize the image distortion due to mask heating in the EUV photolithographic environment. The mask substrate can have a low defect level, such as a high purity single crystal substrate, and have a low level of surface roughness as measured using an atomic force microscope. The mask substrate can transmit light within a predetermined spectrum, such as visible wavelengths, infrared wavelengths near the visible spectrum (near-infrared), and ultraviolet wavelengths. In some embodiments, the mask substrate absorbs EUV wavelengths and DUV wavelengths. FIG. 3 shows a cross-sectional view of an embodiment of a mask 205c including a mask substrate 10 made of a suitable material, such as a low thermal expansion material, according to an embodiment of the present disclosure.

A mask can include a reflective multilayered stack formed over a mask substrate. A reflective multilayered stack can include a plurality of film pairs, such as molybdenum—silicon (Mo/Si) film pairs (e.g., a layer of molybdenum above or below a layer of silicon in each film pair). Alternatively, a reflective multilayered stack may include molybdenum—beryllium (Mo/Be) film pairs, or other suitable materials that are configured to highly reflect EUV light. FIG. 3 shows a reflective multilayered stack 20 including alternating molybdenum layers 17 and silicon layers 19 disposed over a first major surface of the mask substrate 10. In some embodiments, the multilayered stack 20 provides Fresnel resonant reflections across the interfaces between the Mo layer and Si layer, which have different refractive indices and appropriate thicknesses. The thickness of the layers can depend on the wavelength of the incident light and the angle of incidence of the light to be used with the EUV mask. For a specific angle of incidence, the thickness of each of the layers of the multilayered stack 20 can be chosen to achieve maximal constructive interference for light reflected at different interfaces of the multilayered stack 20. An even thickness and low surface roughness of each of the layers in the multilayered stack 20 can provide high-quality Fresnel resonant reflections. In some embodiments, a thickness of each of the layers in the multilayered stack 20 is 5-7 nm. In some embodiments, the number of layers in the multilayered stack 20 is in a range from 20 to 100, although any number of layers is allowed as long as sufficient reflectivity is maintained for imaging a photoresist layer over a target substrate. In some embodiments, a reflectivity of a reflective multilayered stack is higher than about 70%. In some embodiments, the reflective multilayer stack 20 includes about 30 to about 60 alternating layers of Mo and Si. In other embodiments, the multilayer stack 20 includes about 40 to about 50 alternating layers each of Mo and Si. The alternating layers, e.g., Si layers and Mo layers, of the reflective multilayered stack 20 may be formed by any one or more of ion beam deposition (IBD), atomic layer deposition (ALD), physical vapor deposition (PVD), chemical vapor deposition (CVD), plasma-enhanced CVD (PECVD).

The mask 205c can include one or more capping layers disposed over a reflective multilayered stack. FIG. 3 illustrates a first capping layer 23 disposed over the multilayered stack 20. In some embodiments, the first capping layer functions as a buffer layer. In some embodiments, the first capping layer 23 is made of a transition metal element or composition, and alternatively or additionally, a metal oxide, a metal nitride, amorphous carbon, or other suitable materials. In some embodiments, the first capping layer 23 is made of one or more transition metal elements. Embodiments of transition metal elements that are useful in the first capping layer 23 include tantalum, ruthenium, niobium, rhodium, zirconium, and iridium. Other useful materials for the first capping layer include B₄C and graphene. In some embodiments, the first capping layer 23 is made of an alloy of two or more transition metal elements. In some embodiments, the first capping layer 23 is made of a compound including one or more transition metal elements. In some embodiments, the first capping layer 23 is made of any of one or more of a halide, an oxide, a nitride, a carbide, or a boride of one or more transition metal elements. Examples of halides that are useful for a first capping layer include fluorides, chlorides, bromides, and iodides. In some embodiments, the first capping layer 23 is made of one or more of tantalum oxide, ruthenium oxide such as RuO₂, niobium oxide, rhodium oxide such as Rh₂O₃, zirconium oxide, iridium oxide such as IrO₂, ruthenium rhodium alloy, tantalum nitride, ruthenium nitride, niobium nitride, rhodium nitride, tantalum carbide, ruthenium carbide, niobium carbide, rhodium carbide, tantalum boride, ruthenium boride, niobium boride, rhodium boride, tantalum fluoride, ruthenium fluoride, niobium fluoride, rhodium fluoride, tantalum chloride, ruthenium chloride, niobium chloride, rhodium chloride, tantalum bromide, ruthenium bromide, niobium bromide, rhodium bromide, tantalum iodide, ruthenium iodide, niobium iodide, and rhodium iodide. In some embodiments, the first capping layer 23 has a thickness ranging from about 0.5 nm to about 10 nm, from about 1 nm to about 9 nm, from about 2 nm to about 8 nm, from about 3 nm to about 7 nm, or from about 4 nm to about 6 nm.

The mask 205c can include a second capping layer 25 disposed over the reflective multilayered stack 20. In some forms, the first capping layer 23 is disposed over the reflective multilayered stack 20 and the second capping layer 25 is disposed over the first capping layer 23 with the first capping layer between the reflective multilayered stack and the second capping layer. The first capping layer 23 can protect the reflective multilayered stack 20 from oxidation during fabrication processes. Accordingly, the first capping layer can protect and stabilize the reflective multilayered stack. In some embodiments, the first capping layer is omitted from the mask, and the second capping layer is disposed over the reflective multilayered stack. In some embodiments, the second capping layer is disposed directly on the reflective multilayered stack and no first capping layer resides between the second capping layer and the reflective multilayered stack.

FIG. 3 illustrates the second capping layer 25 disposed over the first capping layer 23. In some embodiments, the second capping layer 25 includes at least one of rhodium, a rhodium alloy, ruthenium, a ruthenium alloy, a mixture of ruthenium and B₄C, and inert metal. In some embodiments, inert metal includes at least one niobium, zirconium, and iridium. In some embodiments, the second capping layer 25 is made of rhodium or ruthenium. In some embodiments, the second capping layer 25 is formed entirely of rhodium or ruthenium. In some embodiments, the second capping layer 25 includes one or more materials described herein for use in the first capping layer 23. In some embodiments, the first capping layer 23 includes one or more materials described herein for use in the second capping layer 25. In some embodiments, a mask includes both the first capping layer 23 and the second capping layer 25, and the compositions of the first and second capping layers are different. In some embodiments, a mask includes both the first capping layer 23 and the second capping layer 25, and the compositions of the first and second capping layers are the same. In some embodiments, the second capping layer 25 has a thickness ranging from about 1 nm to about 7 nm, from about 2 nm to about 6 nm, or from about 3 nm to about 5 nm. In some embodiments, the first capping layer 23 and the second capping layer 25 are independently formed by one or more of IBD, ALD, PVD, CVD, and PECVD.

A mask can include a compound layer disposed over one or more capping layers. In some embodiments, the compound layer is located between an absorber layer and a capping layer. In some embodiments, the compound layer is located on top of the capping layer. FIG. 3 shows an embodiment of a compound layer 27 disposed on the second capping layer 25.

The compound layer can have a compact and dense structure that protects the underlying capping layer and reflective multilayer stack from ionic or molecular contamination during mask fabrication, mask cleaning processes, and EUV exposure processes. The compound layer can also provide chemical resistance. The compound layer can lengthen the lifetime of the mask.

In some embodiments, the compound layer includes one or more of a rhodium compound and a ruthenium compound. In some embodiments, a rhodium compound present in the compound layer includes one or more of a rhodium oxide (e.g., RhₓO_{y} where x ranges from about 1 to about 2, and y ranges from about 1 to about 3.5) and a rhodium alloy oxide. In some embodiments, the rhodium alloy oxide includes at least one inert metal. In some embodiments, inert metal of the rhodium alloy oxide includes at least one of niobium, zirconium, and iridium. In some embodiments, the compound layer contains rhodium and one or more elements other than rhodium, and the one or more elements other than rhodium are present in the compound layer in an amount ranging from about 25 atomic % to about 75 atomic % based on a total amount of all atoms in the compound layer. In some embodiments, the compound layer includes one or more compounds including both rhodium and oxygen. In some embodiments, the compound layer includes an atomic ratio of rhodium atoms to oxygen atoms (Rh:O) ranging from about 2:1 to about 1:5. In some embodiments, the compound layer includes one or more of RhO, RhO_{0.5}, RhO_{1.5}, Rh₂O₂, Rh₂O_{2.5}, Rh₂O₃, and Rh₂O_{3.5}. In some embodiments, the compound layer does not include a rhodium nitride. When attempting to form the compound layer over a capping layer including or formed of rhodium using nitrogen plasma, the nitrogen plasma may penetrate the capping layer while not reacting with the rhodium. Thus, in some embodiments, a compound layer including rhodium nitride is not formed. In some embodiments, a ruthenium compound present in the compound layer includes one or more of a ruthenium oxide (e.g., RuₐO_{b} where a ranges from about 1 to about 2, and b ranges from about 1 to about 3.5), a ruthenium nitride (e.g., Ru_{c}N_{d} where c ranges from about 1 to about 2, and d ranges from about 1 to about 3.5), a ruthenium alloy oxide, and a ruthenium alloy nitride. In some embodiments, the ruthenium alloy oxide includes at least one inert metal. In some embodiments, inert metal of the ruthenium alloy oxide includes at least one of niobium, zirconium, and iridium.

Some forms of ruthenium oxide and ruthenium nitride can be naturally formed on a capping layer during mask manufacturing. However, these naturally formed ruthenium oxide and ruthenium nitride materials may have insufficient density and may contribute to decreased mask lifespan and insufficient damage protection for the mask. However, a compound layer formed according to process conditions discussed hereinbelow and including one or more of ruthenium oxide (e.g., RuₐO_{b} above) and ruthenium nitride (e.g., Ru_{c}N_{d} above) by being formed on a capping layer including ruthenium can have a compact structure (e.g., grain size described herein and hexagonal close-packed (HCP) crystalline structure>10%) and provide protection for the mask.

In some embodiments, the compound layer is polymorphic. In some embodiments, the compound layer includes a fraction having an amorphous structure and a fraction having a crystalline structure. In some embodiments, the compound layer includes a fraction having an amorphous structure and a fraction having a HCP crystalline structure. The structure of the compound layer can be determined by methods such as x-ray diffraction (XRD), transmission electron microscopy (TEM), or scanning transmission electron microscopy (STEM). In some embodiments, the compound layer has more than 10 vol. % of the HCP structure and the remainder of the volume of the compound layer is amorphous. In some embodiments, the HCP structure has a unit cell including six atoms of rhodium and nine atoms of elements other than rhodium (e.g., oxygen). In some embodiments, the HCP structure has a unit cell including six atoms of ruthenium and nine atoms of elements other than ruthenium (e.g., oxygen).

In some embodiments, the compound layer includes less than 5 vol. % body centered cubic structure, and in other embodiments, the compound layer does not include body centered cubic structures. In some embodiments, the compound layer includes less than 5 vol. % face centered cubic structure, and in other embodiments, the compound layer does not include face centered cubic structures. In some embodiments, the fraction of the compound layer having the crystalline structure is polycrystalline. In some embodiments, the polycrystalline structure has an average grain size of greater than 0 and less than or equal to about 300 nm, as determined from TEM images. In some embodiments, the polycrystalline structure has an average grain size of ranging from about 10 nm to about 50 nm. In some embodiments, the crystalline structure has a lattice constant of about 5.14. In some embodiments, the compound layer has a thickness of less than about 20 nm, or a thickness ranging from about 5 nm to about 15 nm. In some embodiments, an amorphous fraction of the compound layer includes Rh₂O₃ in an amount from about 0 wt. % to about 65 wt. %, RhO in an amount from about 0 wt. % to about 30 wt. %, and elemental Rh in an amount from amount 0 wt. % to about 5 wt. %. In some embodiments, the thickness of the compound layer is greater than the thickness of the capping layer immediately below the compound layer. In other embodiments, the thickness of the compound layer is less than the thickness of the capping layer immediately below the compound layer.

The mask can include an absorber layer disposed over the compound layer and one or more capping layers. As shown in FIG. 3, in some embodiments the absorber layer 30 is disposed over compound layer 27. The absorber layer 30 is configured to absorb radiation having a wavelength in a range of EUV radiation. The absorber layer 30 can be formed of a single layer or multiple layers. The absorber layer 30 can be patterned by removing sections of the absorber layer. Portions of the absorber layer 30 remaining after patterning absorb light and sections of the mask where the absorber layer has been removed reflects a pattern of light that can be directed to a photoresist layer. The absorber layer 30 can be patterned to define a layer of an integrated circuit (IC) of a semiconductor device. In some embodiments, a pattern such as a hole structure, a line structure, or a cavity structure is formed in the absorber layer 30 so as to expose an underlying structure of a mask, such as the compound layer or the one or more capping layers. In some embodiments, the absorber layer includes one or more of tantalum, boron, tantalum nitride, tantalum boron nitride, titanium, nickel, chromium, ruthenium, platinum, germanium, nickel, lanthanum, molybdenum, palladium, zirconium, nickel silicide, titanium nitride, chromium oxide, aluminum oxide, aluminum-copper alloy, an alloy including two or more thereof, or a compound including two or more thereof. In some embodiments, the absorber layer is formed through a PVD or sputtering process.

The mask 205c can include an anti-reflection layer 35 disposed over the absorber layer 30. In some embodiments, the anti-reflection layer 35 is made of one or more of silicon dioxide, silicon nitride, tantalum borate, tantalum pentoxide, chromium oxide (Cr₂O₃), or indium tin oxide (ITO). The anti-reflection layer 35 can reduce reflections of photolithographic radiation. FIG. 3 shows an anti-reflection layer 35 disposed over the absorber layer 30. The anti-reflection layer 35 can be patterned along with the absorber layer 30 by removing sections of the anti-reflection layer and the absorber layer to expose an underlying structure of a mask, such as the compound layer or one or more capping layers. In some embodiments, the antireflection layer is formed through one or more of ALD, PVD, CVD, and PECVD.

The mask 205c can include a conductive backside coating layer 15 on a major surface of the substrate 10 opposite the reflective multilayered stack 20. FIG. 3 shows a conductive backside coating layer 15 disposed on a second major surface of the substrate 10. The conductive backside coating layer 15 can be used to retain the mask 205c through electrostatic chucking during a photolithographic operation. In an embodiment, the conductive backside coating layer 15 is formed of a ceramic compound including chromium nitride or any suitable material for electrostatic chucking of the mask. In some embodiments, the conductive backside coating layer 15 includes chromium nitride (CrN), chromium oxynitride (CrON), or another suitable conductive material. In some embodiments, the conductive backside coating layer 15 has a thickness ranging from about 20 nm to about 100 nm. The conductive backside coating layer 15 can be formed by CVD, ALD, molecular beam epitaxy (MBE), PVD, pulsed laser deposition, electron-beam evaporation, ion beam assisted evaporation, or any other suitable film-forming method. In some embodiments, the conductive backside coating layer 15 covers an entire backside of the mask substrate 10. In some embodiments, the conductive backside coating layer 15 covers a fraction of the backside of a mask substrate 10.

In some embodiments, a mask blank includes a substrate, a reflective multilayered stack disposed over the substrate, one or more capping layers disposed over the reflective multilayered stack, an absorber layer disposed over the one or more capping layers, and optionally an anti-reflection layer disposed over the absorber layer. In some embodiments, a mask blank includes a substrate, a reflective multilayered stack disposed over the substrate, one or more capping layers disposed over the reflective multilayered stack, a compound layer disposed over the one or more capping layers, an absorber layer disposed over the compound layer, and optionally an anti-reflection layer disposed over the absorber layer. In some embodiments, a mask 205c includes a pattern formed in the absorber layer. In some embodiments, the reflective multilayered stack, the compound layer, and one or more capping layers reflect EUV radiation, while the absorber layer absorbs the EUV radiation.

As shown in FIG. 3, one or more circuit patterns 50 are formed on the mask by partially removing the anti-reflection layer 35 and the absorber layer 30. In addition, the mask includes a black border area 70 surrounding a circuit pattern region. In some embodiments, the black border area penetrates below the reflective multilayered stack and into the substrate. Circuit patterns and black border areas can be formed by one or more etching operations (e.g., O₂ plasma etching).

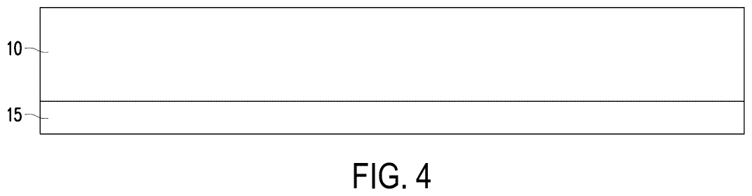

FIGS. 4 to 15 are cross-sectional views of embodiments of methods of manufacturing masks. It should be understood that additional operations can be provided before, during, and after the processes shown in FIGS. 4 to 15, and some of the operations described can be replaced or eliminated, and the order of the operations/processes may be changed.

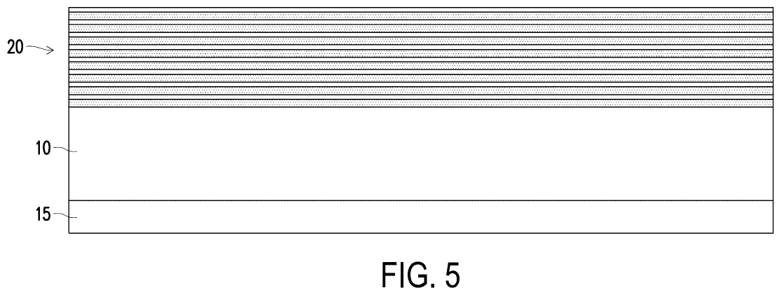

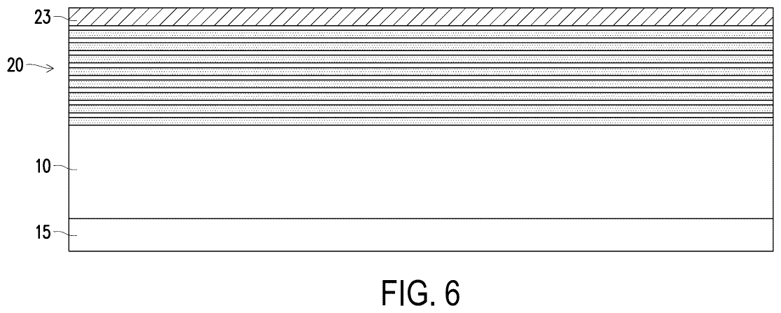

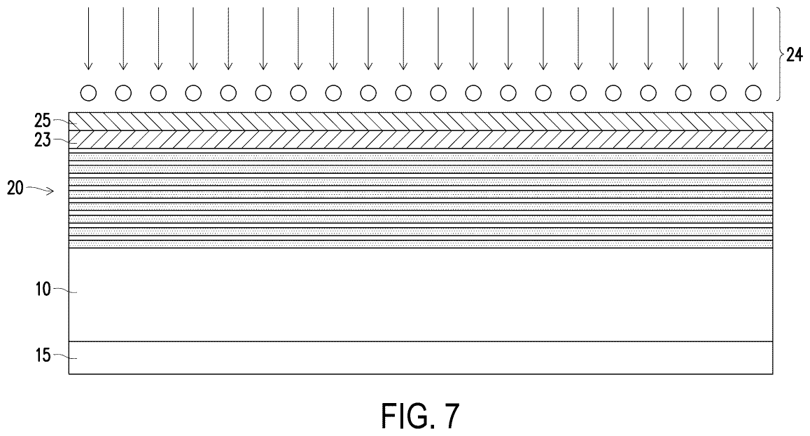

Referring to FIG. 4, a mask substrate 10 is provided, formed, or received. In some embodiments, a backside coating layer 15 is formed or deposited on the backside of the substrate 10. In FIG. 5, a reflective multilayered stack 20 is formed or deposited over the front side of the substrate 10. FIG. 6 illustrates an embodiment where a first capping layer 23 is formed or deposited over the reflective multilayered stack 20 shown in FIG. 5. FIG. 7 illustrates a second capping layer 25 formed or deposited over the first capping layer 23.

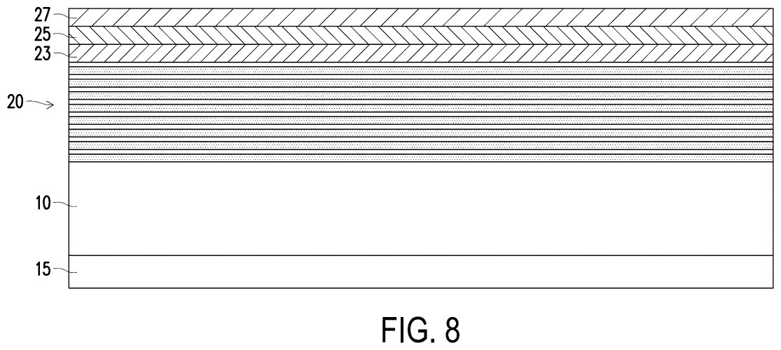

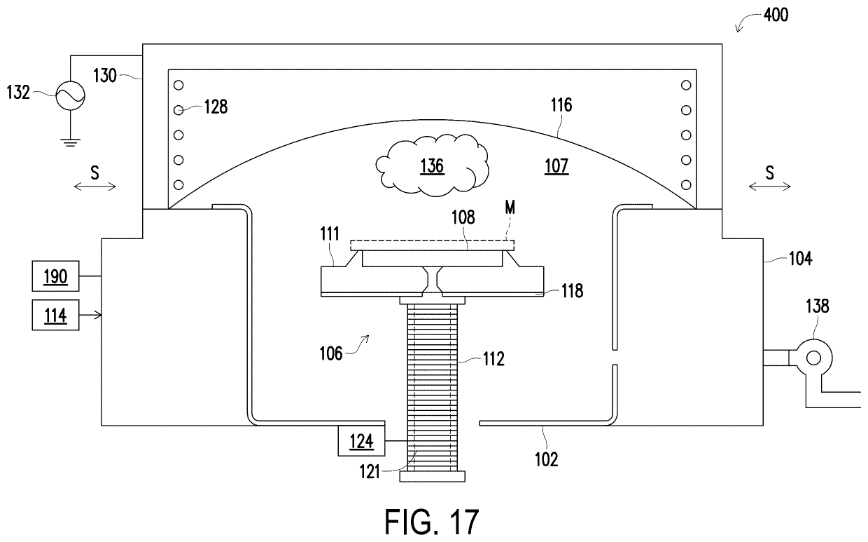

FIG. 7 further illustrates a plasma processing 24 of the second capping layer 25, according to an embodiment. The plasma processing 24 forms or deposits a compound layer 27 over the second capping layer 25, as shown in FIG. 8. In some embodiments, the second capping layer 25 is made of a single element. In some embodiments, the plasma processing converts a portion of the element making up the second capping layer 25 into a compound. In some embodiments, the plasma processing directs plasma to an exposed capping layer made of an element, such as rhodium or ruthenium, to form the compound layer, such as rhodium oxide or ruthenium oxide. In some embodiments, the power applied by a plasma processing apparatus during the plasma treatment process ranges from about 100 W to about 800 W. When the power applied is below the above-noted range, the plasma processing may not sufficiently form the compound layer. The plasma processing may damage an underlying capping layer when the power is applied above the above-noted range. In some embodiments, the temperature of a processing chamber of the apparatus during the plasma processing ranges from about 20 °C to about 50 °C. When the temperature in the chamber is below the above-noted range, the process may not sufficiently form the compound layer. The plasma processing may damage the capping layer when the temperature is above the above-noted range. In some embodiments, the pressure within the chamber ranges from about 1 mTorr to about 10 mTorr during the plasma processing. The plasma processing may insufficiently form the compound layer when the pressure is below the above-noted range. The plasma processing may damage the capping layer when the pressure is maintained above the above-noted range. In some embodiments, a plasma processing apparatus as illustrated in FIG. 17 is used to conduct the plasma processing.

In some embodiments, plasma processing includes applying power to one or more gaseous species in a processing chamber to generate plasma. In various embodiments, the gaseous species include N₂, a combination of N₂ and Ar, a combination of N₂ and He, O₂, a combination of O₂ and Ar, a combination of O₂ and He, a combination of N₂ and O₂, a combination of N₂, O₂, and He, or a combination of N₂, O₂, and Ar. In some embodiments, the compound layer is formed due to decay of a capping layer exposed to the energy of the plasma. In some embodiments, the capping layer supplies a portion of material that forms the compound layer during the plasma processing. In some embodiments, the capping layer is made of rhodium, the plasma converts a portion of the rhodium in the capping layer into the compound layer during the plasma processing. In some embodiments where the capping layer is made of rhodium and the gas supplied to the processing chamber for the plasma processing includes O₂, the generated plasma converts a portion of the rhodium in the capping layer into the compound layer including rhodium and oxygen.

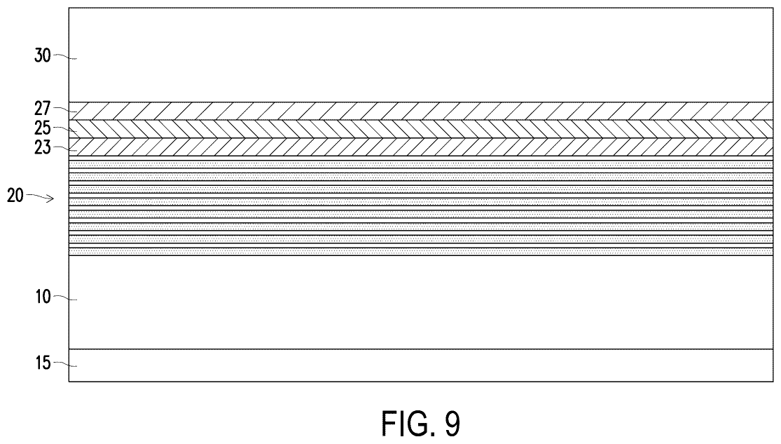

In FIG. 9, an absorber layer 30 is formed or deposited over the compound layer 27. In FIG. 10, circuit pattern 50 is formed in the absorber layer 30 to expose a portion of the compound layer 27. In some embodiments, a circuit pattern is formed using a photolithography process including forming a photoresist layer over the absorber layer, pattern-wise exposing the photoresist to actinic radiation, developing the exposed photoresist layer to form openings in the photoresist layer, and etching the underlying absorber layer through the openings in the photoresist layer using an etching process to form the circuit pattern. In some embodiments, the compound layer functions as an etch stop layer during the etching process.

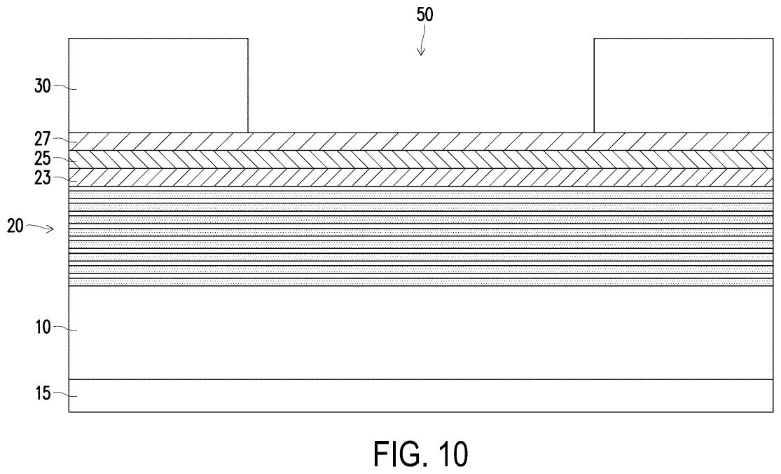

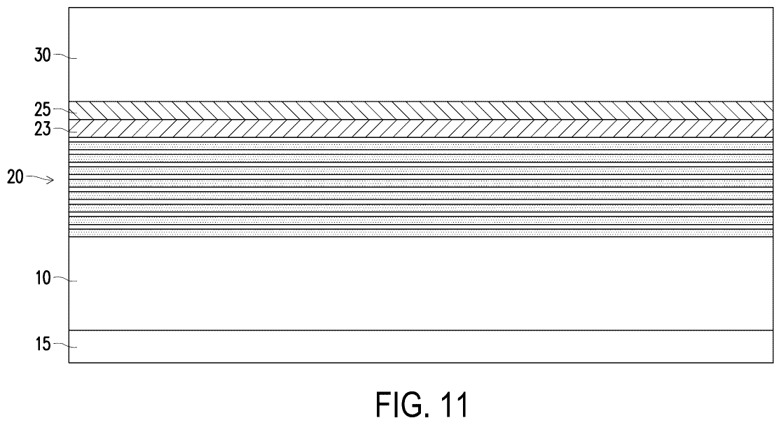

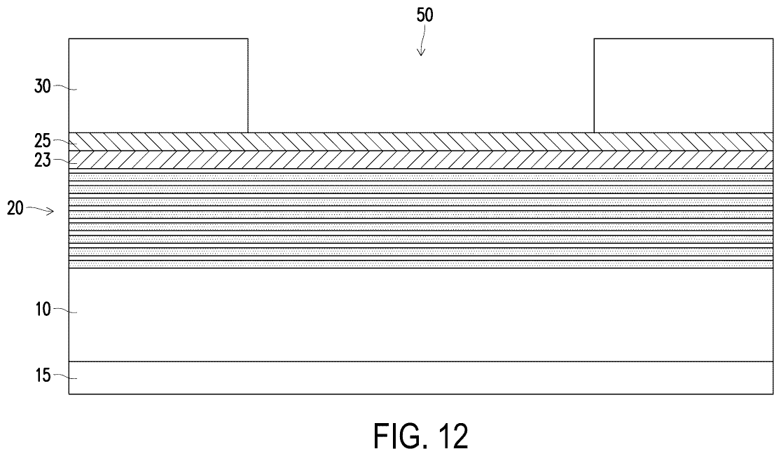

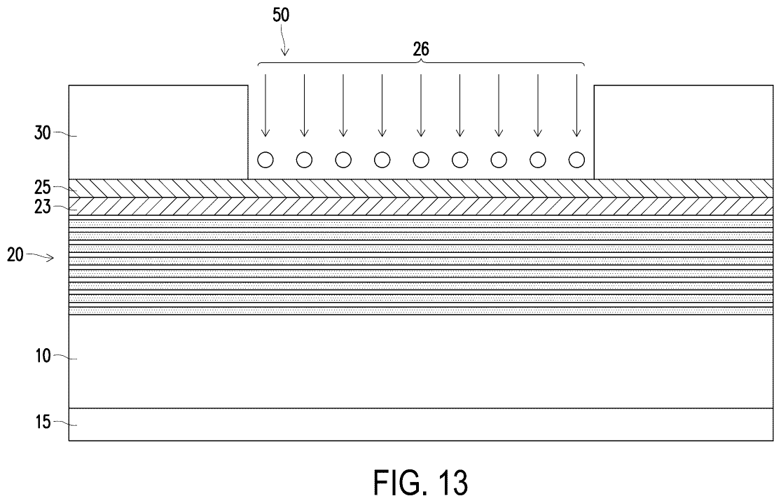

FIG. 11 illustrates another embodiment wherein an absorber layer 30 is formed over the second capping layer 25 shown in FIG. 7. In FIG. 12, a circuit pattern 50 is formed in the absorber layer 30 to expose a portion of the second capping layer 25. In this embodiment, the second capping layer functions as an etch-stop layer when forming the circuit pattern using an etching process. FIG. 13 illustrates plasma processing 26 of the second capping layer 25. The plasma processing 26 forms a compound layer 29 over the second capping layer 25, as shown in FIG. 14. The compound layer 29 is formed over a region of the second capping layer 25 exposed in an opening of the circuit pattern 50. The compound layer 29 can be formed using a plasma processing apparatus and conditions of the plasma processing discussed in connection with forming the compound layer 27 in FIGS. 7 and 8.

In some embodiments, the compound layer resides between the capping layer and the absorber layer in one or more regions outside an opening through an absorber layer. In some embodiments, the compound layer does not reside over the capping layer in regions outside an opening through an absorber layer.

FIG. 15 illustrates another embodiment of a compound layer 31 formed over the second capping layer 25, as shown in FIG. 13. The compound layer 31 can be formed using the plasma processing apparatus and conditions of the plasma processing discussed in connection with forming the compound layer 27 in FIGS. 7 and 8. The compound layer 31 can also extend between the absorber layer 30 and the capping layer 25. In some embodiments, a value of one or more of power applied by the plasma processing apparatus, temperature in the processing chamber, and pressure in the processing chamber is higher when forming compound layer 31 than when forming compound layer 29. In some embodiments, the compound layer is formed to extend between the capping layer and the absorber layer by controlling the power applied by the plasma processing apparatus during the plasma treatment process to a range from about 100 W to about 1000 W. When the power applied is below the above-noted range, the plasma processing may not sufficiently form the compound layer and may not extend the compound layer between the absorber layer and the capping layer. The plasma processing may damage an underlying capping layer when the power is applied above the above-noted range. In some embodiments, a compound layer is formed to extend between the capping layer and the absorber layer by controlling the temperature of the processing chamber of the apparatus during the plasma processing to a range from about 20 °C to about 50 °C. When the temperature in the chamber is below the above-noted range, the process may not sufficiently form the compound layer and may not extend the compound layer between the absorber layer and the capping layer. The plasma processing may damage the capping layer when the temperature is above the above-noted range. In some embodiments, a compound layer can be formed to extend between the capping layer and the absorber layer by controlling the pressure within the chamber to a range from about 1 mTorr to about 15 mTorr during the plasma processing. The plasma processing may insufficiently form the compound layer and may not extend the compound layer between the absorber layer and the capping layer when the pressure is below the above-noted range. The plasma processing may damage the capping layer when the pressure is maintained above the above-noted range. In some embodiments, the processing temperature in the chamber of the plasma processing apparatus is higher when forming compound layer 31 than when forming compound layer 29. In some embodiments, the processing pressure in a chamber of the plasma processing apparatus is higher when forming compound layer 31 than when forming compound layer 29. In some embodiments, the power applied to generate the plasma is higher when forming the extended compound layer 31 than when forming the compound layer 29. By increasing the magnitude of one or more processing conditions during the plasma processing, the plasma becomes more energized and extends the compound layer 31 in a region between the absorber layer 30 and the second capping layer 25 proximal to the opening 50, as shown in FIG. 15. In some embodiments, a distance L1 from an edge of the absorber layer 30 at the circuit pattern 50 to an end of the compound layer between the absorber layer 30 and the second capping layer 25 is greater than about 0.5 nm. In some embodiments, the distance ranges from about 0.7 nm to about 1.5 nm. A thickness of the compound layer 31 can range from about 1 nm to about 20 nm in a region between the absorber layer and the one or more capping layers.

In various embodiments, the compound layer 27, 29, 31 is formed on a capping layer including ruthenium using processing conditions described herein, and the compound layer 27, 29, 31 includes one or more of ruthenium oxide ruthenium oxide (e.g., RuₐO_{b} above) and ruthenium nitride (e.g., Ru_{c}N_{d} above) the compound layer has a compact structure (e.g., grain size described herein and fraction of HCP>10%). Such a compound layer can provide protection for the mask. In some embodiments, the relatively less compact and naturally formed ruthenium oxide and ruthenium nitride materials are not formed in a capping layer including ruthenium when using the processing conditions described herein. In some embodiments, a compound layer 27, 29, 31 as respectively shown in FIGS. 10, 14, and 15, does not include relatively less compact and naturally formed ruthenium oxide and ruthenium nitride when formed on the capping layer including ruthenium using processing conditions described herein.

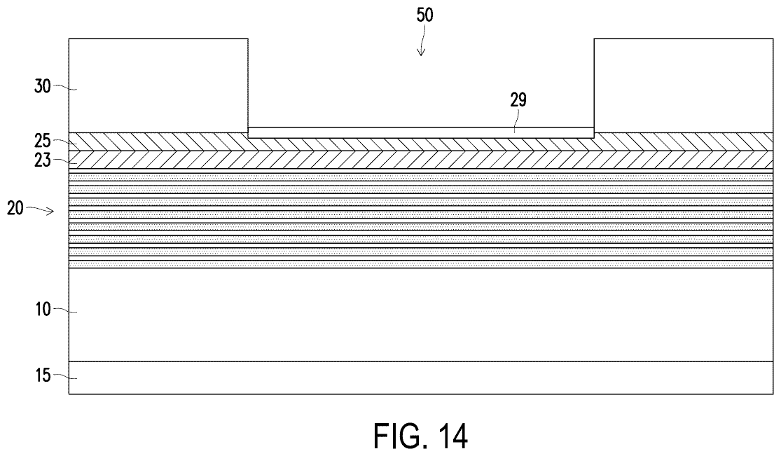

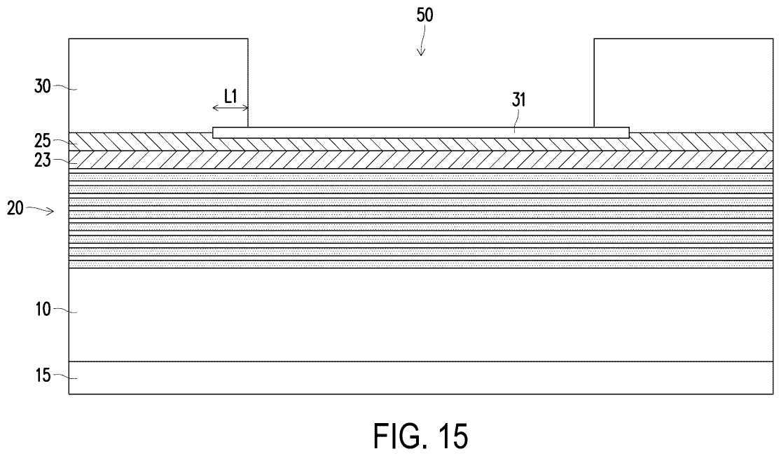

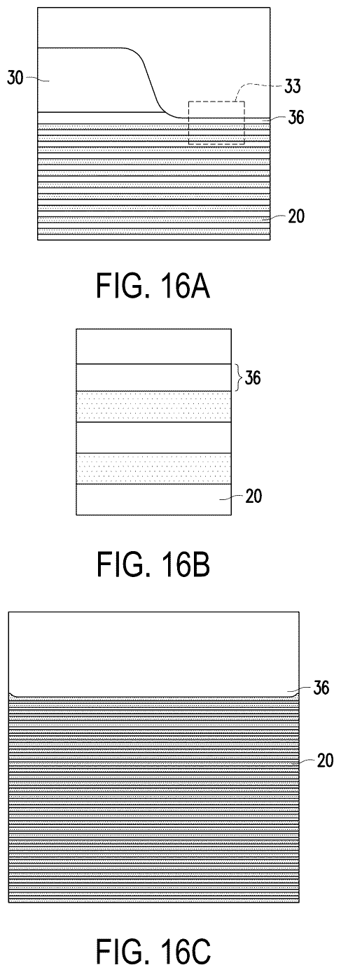

FIG. 16A illustrates a cross-section view of an embodiment of a mask including an absorber layer 30 disposed over a compound layer 36. FIG. 16B illustrates a cross-section view of an enlarged portion of the mask in region 33 shown in FIG. 16A. FIG. 16C illustrates a cross-section view of another embodiment of a mask where the compound layer 36 protects a reflective multilayered stack 20 from ion penetration and degradation.

FIG. 17 illustrates a plasma processing apparatus 400 according to some embodiments. The apparatus 400 includes a base 102 and an outer wall 104 that includes a port for receiving a mask substrate M in chamber 107. In some embodiments, mask substrate includes at least a low thermal expansion substrate, a reflective multilayered stack disposed over the low thermal expansion substrate, and one or more capping layers disposed over the reflective multilayered stack. The apparatus 400 further includes a substrate lift 106, which includes a pedestal 108, an insulator 111, an insulator base 118, a shaft 121, and a bellows assembly 112. The mask substrate M is seated upon pedestal 108 including an RF-biased, disk-shaped platform made from aluminum, titanium, or other non-reactive metal. The pedestal 108 is supported and insulated by insulator 111.

The insulator 111 is a one-piece insulator, including a non-reactive insulative material such as ceramic or quartz in some embodiments. The insulator 111 insulates the sides and bottom of the pedestal 108 and collimates the RF power to the top surface of pedestal 108 and, hence, through mask substrate M. The insulator 111 is supported by insulator base 118. The shaft 121 supports pedestal 108, insulator 111, and insulator base 118, and moves the mask substrate M vertically between a release position, where mask substrate M is introduced to and is removed from the chamber 107, and a processing position, where mask substrate M is maintained during the plasma treatment process. The bellows assembly 112 isolates and surrounds the shaft 121 when the chamber 107 is under vacuum. The chamber cover 116 covers and seals the chamber 107 during the plasma treatment process.

The substrate support including the pedestal 108, the insulator 111, the insulator base 118, the shaft 121, and the bellows assembly 112 functions as an RF cathode connected to an RF power supply 124. The chamber 107 also includes one or more deposition shields and cover rings circumscribing various chamber components to prevent unwanted reaction between the components and process materials.

To create a desired plasma for processing the mask substrate M an RF coil 128 is provided. The coil 128 is disposed within a resonator housing 130 disposed above the chamber cover 116 (or lid). The coil 128 is vertically aligned with the outer walls 104 and is powered by an RF coil power source 132. During the plasma treatment process, RF power is supplied, and a gas inlet 114 introduces gases suitable for performing the plasma treatment process (e.g. O₂). A plasma 136 is created when the RF coil 128 inductively couples power from the RF coil power source 132 into the process gas. RF power is then supplied to chamber 107, causing high voltage and high current to strike the gas in the chamber. When the RF power is supplied to chamber 107, the bottom surface of chamber cover 116 acts as an anode and the substrate support acts as a cathode. Charged ions are attracted to the oppositely charged substrate support. The ions react with an exposed capping layer of the mask substrate M. To establish and maintain the necessary environmental conditions in the chamber 107, a pressure control device 138 is connected to the chamber 107. The pressure control device 138 is, for example, a turbo pump or other similar pump capable of establishing near vacuum conditions (i.e., chamber pressure in the mTorr range).

The apparatus 400 is controlled by a system controller 190 that facilitates the control and automation of the apparatus 400 and typically includes a central processing unit (CPU), memory, and support circuits (or I/O). The CPU may be one of any form of computer processors that are used in industrial settings for controlling various system functions, substrate movement, chamber processes, and support hardware (e.g., sensors, robots, motors, etc.), and monitor the processes (e.g., substrate support temperature, power supply variables, chamber process time, I/O signals, etc.). The memory is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. The support circuits are also connected to the CPU for supporting the processor in a conventional manner. The support circuits include cache, power supplies, clock circuits, input/output circuitry, subsystems, and the like. A program (or computer instructions) readable by the system controller 190 determines which tasks to be performed on the substrate. The program is software readable by the system controller 190 that includes code to perform tasks relating to monitoring, execution and control of the movement and various process recipe tasks and recipe steps being performed in the apparatus 400. For example, the system controller 190 includes program code that includes a substrate positioning instruction set to operate the substrate support, a gas flow control instruction set to operate flow control valves to set a flow of gas to the processing chamber 107, a gas pressure control instruction set to operate a throttle valve or gate valve to maintain a pressure in the processing chamber 107, a temperature control instruction set to control a temperature control system in the substrate support, and a process monitoring instruction set to monitor the process in the processing chamber 107.

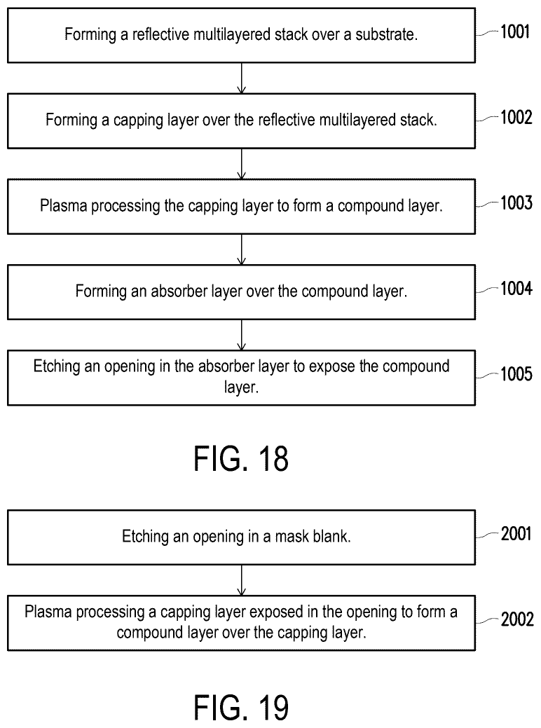

FIG. 18 shows a flow-chart of a method of manufacturing a mask according to some embodiments. The method includes an operation 1001 of forming a reflective multilayered stack 20 over a substrate 10. The method includes an operation 1002 of forming a capping layer 23, 25 over the reflective multilayer stack. The method further includes an operation 1003 of plasma processing the capping layer to form a compound layer 27. The method includes an operation 1004 of forming an absorber layer 30 over the compound layer 27. The method further includes an operation 1005 of etching an opening 50 in the absorber layer to expose the compound layer 27.

FIG. 19 shows a flow-chart of a method of manufacturing a mask according to some embodiments. The method includes an operation 2001 of etching an opening in a mask blank. The method includes an operation 2002 of plasma processing a capping layer 25 exposed in the opening to form a compound layer 29, 31 over the capping layer.

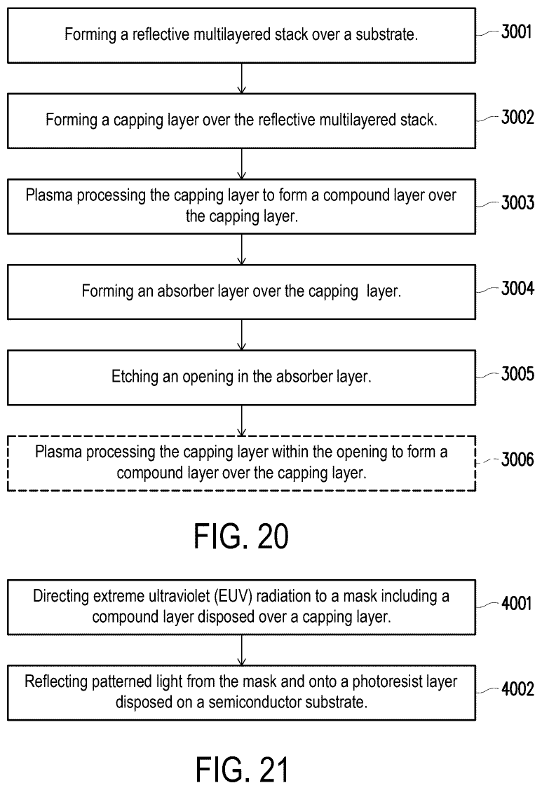

FIG. 20 shows a flow-chart of a method of manufacturing a mask according to some embodiments. The method includes an operation 3001 of forming a reflective multilayered stack 20 over a substrate 10. The method includes an operation 3002 of forming a capping layer 23, 25 over the reflective multilayer stack. The method optionally includes an operation 3003 of plasma processing the capping layer 23, 25 to form a compound layer 27 over the capping layer. The method further includes an operation 3004 of forming an absorber layer 30 over the capping layer 23, 25. The method further includes an operation 3005 of etching an opening 50 in the absorber layer 30. The method optionally includes an operation 3006 of plasma processing the capping layer 23, 25 within the opening to form a compound layer 29, 31 over the capping layer.

FIG. 21 shows a flow-chart of a method of manufacturing a semiconductor device according to some embodiments. The method includes an operation 4001 of directing EUV radiation to a mask including a compound layer 27, 29, 31 disposed over a capping layer 23, 25 according to embodiments of this disclosure and then an operation 4002 of reflecting patterned light from the mask onto a photoresist layer disposed on a semiconductor substrate. The EUV exposed photoresist layer is subsequently developed to form a pattern. The pattern corresponds to an integrated circuit to be formed on the substrate. Additional semiconductor device manufacturing operations are subsequently performed to obtain a desired semiconductor device. In some embodiments, the desired semiconductor device includes active components such diodes, field-effect transistors (FETs), metal-oxide semiconductor field effect transistors (MOSFET), complementary metal-oxide semiconductor (CMOS) transistors, bipolar transistors, high voltage transistors, high frequency transistors, sheet FETs such as nanosheet FETs, FinFETs, gate-all-around FETs (GAA FETs), other three-dimensional (3D) FETs, other memory cells, and combinations thereof

A compound layer of a mask protects underlying layers of the mask such as the reflective multilayered stack and the capping layer. In some embodiments of the disclosure, the compound layer prevents ions or other small molecules from diffusing into the mask and damaging or contaminating the reflective multilayered stack. In some embodiments of the disclosure, the compound layer also provides general chemical resistance to protect the reflective multilayered stack.

According to an embodiment, a method of manufacturing a mask includes forming a reflective multilayered stack over a substrate. The method further includes forming a capping layer over the reflective multilayered stack, wherein the capping layer includes at least one of rhodium and ruthenium. The method further includes plasma processing the capping layer to form a compound layer on the capping layer, wherein the compound layer includes at least one of rhodium and ruthenium, and at least one additional element. The method further includes forming an absorber layer over the compound layer. The method further includes etching an opening in the absorber layer to expose the compound layer. In an embodiment, the at least one additional element is present in the compound layer in an amount ranging from about 25 atomic % to about 75 atomic % based on a total amount of all atoms in the compound layer. In an embodiment, the compound layer includes rhodium and oxygen. In an embodiment, a ratio of rhodium to oxygen in the compound layer ranges from 2:1 to 1:5. In an embodiment, the capping layer supplies the rhodium to form the compound layer during the plasma processing. In an embodiment, the compound layer includes at least one compound of the formula RhₓO_{y}, wherein x ranges from 1 to 2, and y ranges from 1 to 3.5. In an embodiment, the opening comprises a circuit pattern. In an embodiment, the plasma processing includes generating at least one of a nitrogen plasma or an oxygen plasma.

According to another embodiment, a method of manufacturing a mask includes etching an opening in a mask blank. The mask blank includes a substrate, a reflective multilayered stack disposed over the substrate, a capping layer disposed over the reflective multilayered stack, wherein the capping layer includes ate least one of rhodium and ruthenium, and an absorber layer disposed over the capping layer, wherein the opening exposes the capping layer. The method further includes plasma processing the capping layer to form a compound layer over the capping layer within the opening, wherein the compound layer includes oxygen and at least one of rhodium and ruthenium. In an embodiment, the capping layer supplies the at least one rhodium and ruthenium for the compound layer during the plasma processing. In an embodiment, a ratio of rhodium to oxygen in the compound layer ranges from 2:1 to 1:5. In an embodiment, the plasma processing further forms the compound layer in a region between the absorber layer and the capping layer proximal to the opening. In an embodiment, the compound layer includes at least one of the formula RhₓO_{y}, wherein x ranges from 1 to 2, and y ranges from 1 to 3.5.

According to another embodiment, a mask for extreme ultraviolet (EUV) photolithography includes a reflective multilayered stack disposed over a substrate. The mask further includes a first capping layer disposed over the reflective multilayered stack; a second capping layer disposed over the first capping layer, wherein the second capping layer includes at least one of rhodium and ruthenium and has a different composition than the first capping layer; an absorber layer disposed over the second capping layer; and an opening formed in the absorber layer and exposing a compound layer disposed over the second capping layer, wherein the compound layer includes at least one a rhodium compound and a ruthenium compound. In an embodiment, the compound layer resides between the absorber layer and the second capping layer in one or more regions outside the opening. In an embodiment, the compound layer extends from the opening to a region between the absorber layer and the second capping layer proximal to the opening. In an embodiment, the compound layer includes rhodium and oxygen. In an embodiment, a ratio of rhodium to oxygen in the compound layer ranges from 2:1 to 1:5. In an embodiment, the compound layer includes at least one compound of the formula RhₓO_{y}, wherein x ranges from 1 to 2, and y ranges from 1 to 3.5. In an embodiment, the opening comprises a circuit pattern.

According to another embodiment, a method of manufacturing a semiconductor device, the method includes directing extreme ultraviolet (EUV) radiation to a mask; and reflecting patterned light from the mask and onto a photoresist layer disposed on a semiconductor substrate. The mask includes a reflective multilayered stack disposed over a substrate; a capping layer disposed over the reflective multilayered stack, wherein the capping layer includes at least one of rhodium and ruthenium; an absorber layer disposed over the capping layer; and an opening formed in the absorber layer and exposing a compound layer disposed over the capping layer, wherein the compound layer includes at least one of rhodium and ruthenium. In an embodiment, the compound layer further includes at least one additional element other than the at least one of rhodium and ruthenium. In an embodiment, the at least one additional element is present in the compound layer in an amount ranging from about 25 atomic % to about 75 atomic % based on a total amount of all atoms in the compound layer. In an embodiment, the compound layer resides between the absorber layer and the capping layer in regions outside the opening. In an embodiment, the compound layer extends from the opening to a region between the absorber layer and the capping layer proximal to the opening. In an embodiment, the compound layer includes rhodium and oxygen. In an embodiment, a ratio of rhodium to oxygen in the compound layer ranges from 2:1 to 1:5. In an embodiment, the compound layer includes at least one compound of the formula RhₓO_{y}, wherein x ranges from 1 to 2, and y ranges from 1 to 3.5. In an embodiment, the opening comprises a circuit pattern.

According to another embodiment, a mask for extreme ultraviolet (EUV) photolithography includes a reflective multilayered stack disposed over a substrate; a capping layer disposed over the reflective multilayered stack, wherein the capping layer includes ruthenium; a compound layer disposed over the capping layer and including ruthenium and oxygen; an absorber layer disposed over the capping layer; and an opening formed in the absorber layer, wherein the compound layer is exposed in the opening. In an embodiment, the compound layer resides between the capping layer and the absorber layer in at least one region outside the opening. In an embodiment, the compound layer does not reside over the capping layer in regions outside the opening.

According to another embodiment, a method of manufacturing a mask includes forming a reflective multilayered stack over a substrate; forming a capping layer over the reflective multilayered stack; plasma processing the capping layer to form a compound layer on the capping layer, wherein the compound layer includes oxygen and at least one of rhodium and ruthenium; forming an absorber layer over the capping layer; and etching an opening in the absorber layer. In an embodiment, the plasma processing the capping layer is conducted after etching the opening. In an embodiment, the plasma processing the capping layer forms the compound layer over the capping layer within the opening. In an embodiment, the plasma processing the capping layer further forms the compound layer in a region between the capping layer and the absorber layer. In an embodiment, the plasma processing is conducted before forming the absorber layer over the capping layer, and the compound layer resides between the absorber layer and the capping layer.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a mask, the method comprising:
forming a reflective multilayered stack over a substrate;
forming a capping layer over the reflective multilayered stack, wherein the capping layer includes at least one of rhodium and ruthenium;
plasma processing the capping layer to form a compound layer on the capping layer, wherein the compound layer includes at least one of rhodium and ruthenium, and at least one additional element;
forming an absorber layer over the compound layer; and
etching an opening in the absorber layer to expose the compound layer.

2. The method of claim 1, wherein the at least one additional element are present in the compound layer in an amount ranging from about 25 atomic % to about 75 atomic % based on a total amount of all atoms in the compound layer.

3. The method of claim 1, wherein the compound layer comprises rhodium and oxygen.

4. The method of claim 3, wherein a ratio of rhodium to oxygen in the compound layer ranges from 2:1 to 1:5.

5. The method of claim 4, wherein the capping layer supplies the rhodium to form the compound layer during the plasma processing.

6. The method of claim 1, wherein the compound layer includes at least one compound of the formula RhₓO_{y}, wherein x ranges from 1 to 2, and y ranges from 1 to 3.5.

7. The method of claim 1, wherein the opening comprises a circuit pattern.

8. The method of claim 6, wherein the plasma processing includes generating at least one of a nitrogen plasma or an oxygen plasma.

9. A method of manufacturing a mask comprising:
etching an opening in a mask blank, wherein the mask blank comprises:
a substrate,
a reflective multilayered stack disposed over the substrate,
a capping layer disposed over the reflective multilayered stack, wherein the capping layer includes at least one of rhodium and ruthenium, and
an absorber layer disposed over the capping layer, wherein the opening exposes the capping layer; and
plasma processing the capping layer to form a compound layer over the capping layer within the opening, wherein the compound layer includes oxygen and at least one of rhodium and ruthenium.

10. The method of claim 9, wherein the capping layer supplies the at least one of rhodium and ruthenium for the compound layer during the plasma processing.

11. The method of claim 9, wherein a ratio of rhodium to oxygen in the compound layer ranges from 2:1 to 1:5.

12. The method of claim 9, wherein the plasma processing further forms the compound layer in a region between the absorber layer and the capping layer proximal to the opening.

13. The method of claim 9, wherein the compound layer includes at least one compound of the formula RhₓO_{y}, wherein x ranges from 1 to 2, and y ranges from 1 to 3.5.

14. A mask for extreme ultraviolet (EUV) photolithography, comprising:
a reflective multilayered stack disposed over a substrate;
a first capping layer disposed over the reflective multilayered stack;
a second capping layer disposed over the first capping layer, wherein the second capping layer includes at least one of rhodium and ruthenium and has a different composition than the first capping layer;
an absorber layer disposed over the second capping layer; and
an opening formed in the absorber layer and exposing a compound layer disposed over the second capping layer, wherein the compound layer includes at least one of a rhodium compound and a ruthenium compound.

15. The mask of claim 14, wherein the compound layer resides between the absorber layer and the second capping layer in at least one region outside the opening.

16. The mask of claim 14, wherein the compound layer extends from the opening to a region between the absorber layer and the second capping layer proximal to the opening.

17. The mask of claim 14, wherein the compound layer includes rhodium and oxygen.

18. The mask of claim 17, wherein a ratio of rhodium to oxygen in the compound layer ranges from 2:1 to 1:5.

19. The mask of claim 17, wherein the compound layer includes at least one compound of the formula RhₓO_{y}, wherein x ranges from 1 to 2, and y ranges from 1 to 3.5.

20. The mask of claim 14, wherein the opening comprises a circuit pattern.
